(19) United States
(12) Patent Application Publication
(10) Pub. No.: US 2024/0213131 A1
(43) Pub. Date: Jun. 27, 2024

(54) DIRECT PLATING OF COPPER ON DIELECTRICS FOR GLASS CORE PLATING

(71) Applicant: Intel Corporation, Santa Clara, CA (US)

(72) Inventors: Yi YANG, Gilbert, AZ (US); Andrew WENTZEL, Tempe, AZ (US); Marcel WALL, Phoenix, AZ (US); Suddhasattwa NAD, Chandler, AZ (US)

(21) Appl. No.: 18/089,499

(22) Filed: Dec. 27, 2022

(51) Int. Cl. H01L 23/498; C25D 3/38; C25D 7/12; C25D 17/00; H01L 23/15

(52) U.S. Cl. CPC H01L 23/49827; C25D 3/38; C25D 7/12; C25D 17/001; H01L 23/15; H01L 24/16; H01L 2224/16225

(57) ABSTRACT

In an embodiment, a package substrate is described. In an embodiment, the package substrate comprises a layer, where the layer is a dielectric material. In an embodiment, a via opening is provided through a thickness of the layer. In an embodiment, a conductive via is in the via opening, where the conductive via has a substantially uniform composition throughout a thickness of the conductive via. In an embodiment the conductive via directly contacts the layer.

### TECHNICAL FIELD

Embodiments of the present disclosure relate to electronic packages, and more particularly to package substrates with glass cores that include through glass vias (TGVs) with direct copper plating.

### BACKGROUND

Laser through holes (LTHs) provide vertical electrical connections through a glass substrate. In some instances, the vias through the LTHs may be considered through glass vias (TGVs). LTHs and TGVs are used in advanced packaging solutions, such as glass interposers and wafer-level packaging of microelectromechanical systems (MEMS). However, LTHs are challenging to realize because the via holes in glass typically do not have a sufficiently high-quality sidewall profile for super-conformal electroplating of metal into the via holes. Particularly, the traditional copper plating cannot be realized on a non-conductive substrate by typical electrochemical plating techniques. Additionally, when it comes to the high aspect ratio LTHs, the sidewall surfaces are too rough for providing good step coverage, defect free, and strong adhesion strength at the interface between the LTH and the copper of the TGV.

Typically, a seed layer is applied over the glass substrate in order to have a conductive layer in order to plate the TGV. However, as noted above, high surface roughness and high aspect ratios of the LTH result in poor seed layer coverage. As such, the plating up from the seed layer can result in voids, defects, and poor adhesion to the glass substrate.

### BRIEF DESCRIPTION OF THE DRAWINGS

FIG. 1A is a cross-sectional illustration of a glass core with a through glass via (TGV) that is plated up from a seed layer that is formed over the surfaces of the glass core.

FIG. 1B is a cross-sectional illustration of the glass core in FIG. 1A after the seed layer is removed with a seed layer etching process.

FIG. 1C is a zoomed in cross-sectional illustration of the glass core that demonstrates the presence of the seed layer between the TGV and the glass core, and the roughened surfaces of the pad over the glass core.

FIG. 2A is a cross-sectional illustration of a dielectric layer on which a conductive layer is desired, in accordance with an embodiment.

FIG. 2B is a cross-sectional illustration of the dielectric layer during a protonating process that includes a plasma exposure, in accordance with an embodiment.

FIG. 2C is a cross-sectional illustration of the dielectric layer after the surface has been protonated to have dangling —OH bonds, in accordance with an embodiment.

FIG. 2D is a cross-sectional illustration of an electroplating setup used to form a metallic layer over the dielectric layer, in accordance with an embodiment.

FIG. 2E is a cross-sectional illustration of the dielectric layer after the electroplating bath is ionized to form —O⁻ dangling bonds that are reactive to metal ions, in accordance with an embodiment.

FIG. 2F is a cross-sectional illustration of the dielectric layer after the metal ions are ionically bonded to the surface of the dielectric layer, in accordance with an embodiment.

FIG. 3A is a cross-sectional illustration of a glass core of a package substrate, in accordance with an embodiment.

FIG. 3B is a cross-sectional illustration of the package substrate after a via opening is formed through the glass core, in accordance with an embodiment.

FIG. 3C is a cross-sectional illustration of the package substrate after a patterned resist layer is provided over the surfaces of the package substrate, in accordance with an embodiment.

FIG. 3D is a cross-sectional illustration of the package substrate during exposure to a plasma that is used to protonate the exposed surfaces of the glass core, in accordance with an embodiment.

FIG. 3E is a cross-sectional illustration of the package substrate with a protonated glass core surface, in accordance with an embodiment.

FIG. 3F is a cross-sectional illustration of the package substrate after the TGV is plated through the glass core, in accordance with an embodiment.

FIG. 3G is a cross-sectional illustration of the package substrate after the resist layer is stripped, in accordance with an embodiment.

FIG. 3H is a zoomed in cross-sectional illustration of a portion of the package substrate that illustrates smooth metal surfaces and a direct connection between the TGV and the glass core, in accordance with an embodiment.

FIG. 4 is a cross-sectional illustration of an electronic system that includes a package substrate with TGVs through a glass core that directly contact the glass core, in accordance with an embodiment.

FIG. 5 is a schematic of a computing device built in accordance with an embodiment.

### EMBODIMENTS OF THE PRESENT DISCLOSURE

Described herein are package substrates with glass cores that include through glass vias (TGVs) with direct copper plating, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, it is difficult to plate high quality vias in high aspect ratio laser through holes (LTHs) in dielectric substrates. Particularly, high surface roughness, tapered sidewalls, and the like make the deposition of a uniform seed layer difficult. In existing solutions, a sputtering process is generally used in order to deposit a seed layer comprising titanium and copper on the surfaces of the dielectric substrate. After blanket deposition of the seed layer, an electroplating process is used to plate the vias in the dielectric layer. However, due to poor seed layer coverage, the via may include voids or other defects. Additionally, the adhesion between the via and the dielectric layer is generally poor. Furthermore, the seed layer needs to be removed in subsequent processing operations. This results in a roughened surface for any existing pads on the dielectric layer over the vias.

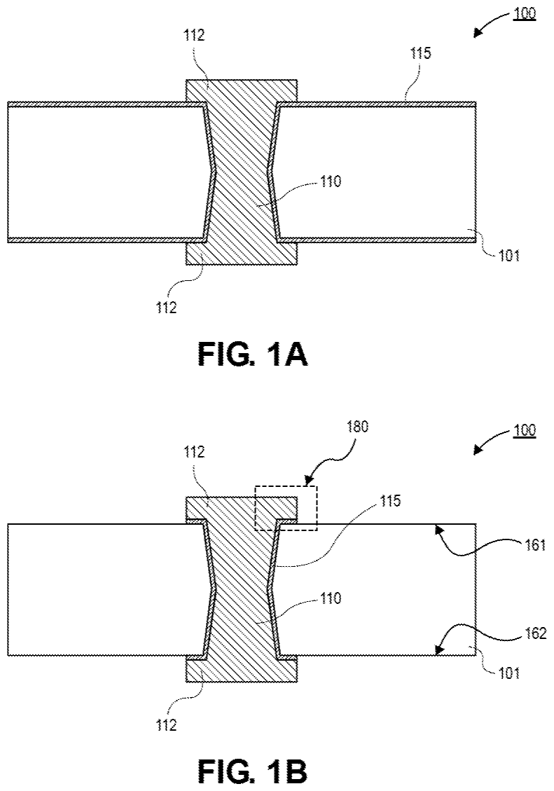

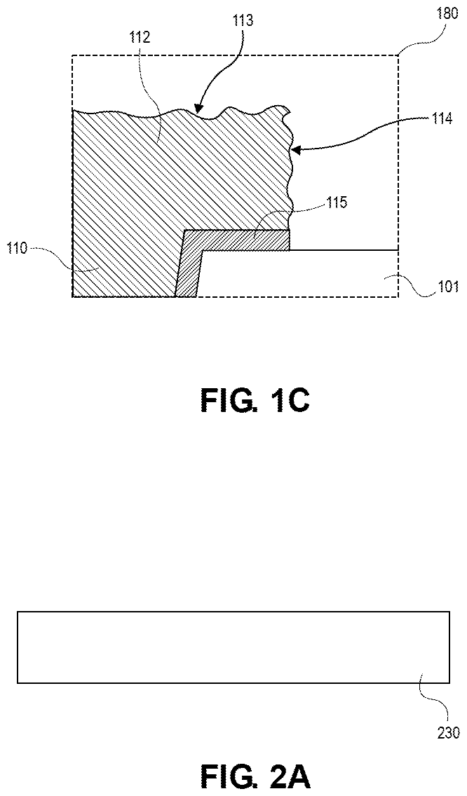

FIGS. 1A-1C provide context for an existing process flow that illustrates formation of a package substrate 100 with a through glass via (TGV) 110 in a glass core 101. Referring now to FIG. 1A, a cross-sectional illustration of a glass core 101 with a TGV 110 and pads 112 above and below the TGV 110 is shown. The glass core 101 may be any thickness and any suitable glass material. The TGV 110 may be plated up from a seed layer 115. The seed layer 115 may comprise copper and/or titanium. As shown, a distinct portion of the seed layer 115 may be provided between the TGV 110 and the glass core 101. That is, the TGV 110 (e.g., comprising copper) may be separated from the glass core 101 by the seed layer 115. While it may be difficult to distinctly differentiate the TGV 110 from the seed layer 115 using some analysis techniques, the existence of the seed layer 115 may be detectable by the presence of an element that is different than the copper of the TGV 110. For example, titanium may be detected using one or more material characterization techniques such as EDX or the like.

Additionally, the illustration in FIG. 1A is an idealized representation of the interfaces between the seed layer 115 and the glass core 101. Particularly, it is to be appreciated that the sidewalls of the glass core 101 around the TGV 110 may be roughened, and the seed layer 115 may not be perfectly uniform, as shown in FIG. 1A. As a result, the plating of the TGV 110 may result in voids, defects, or the like.

Referring now to FIG. 1B, a cross-sectional illustration of the package substrate 100 after a seed layer 115 etching process is performed is shown. The seed layer 115 etching process may be referred to as a flash etching process. Particularly, a timed wet etch may be used. The duration of the wet etch may be substantially short in order to etch through the exposed portions of the seed layer 115 without significantly etching the pads 112 above and below the TGV 110. As shown, the etching of the seed layer 115 does not remove the seed layer 115 from between the TGV 110 and the glass core 101 or from between the pads 112 and the glass core 101. However, a top surface 161 and a bottom surface 162 of the glass core 101 are exposed. Despite being used for a short duration, the surfaces of the pads 112 may be somewhat etched. The etching of the pads 112 may result in a roughened surface, as will be shown in the zoomed in illustration of region 180.

Referring now to FIG. 1C, a zoomed in cross-sectional illustration of region 180 is shown. Region 180 clearly shows the seed layer 115 being between the TGV 110 and the glass core 101, and the seed layer 115 being between the pad 112 and the glass core 101. Additionally, the zoomed in illustration illustrates the roughened surfaces of the pad 112. For example, a top surface 113 and a sidewall surface 114 of the pad 112 may be roughened. The seed etching process may result in an average surface roughness (Ra) that is approximately 50 nm or greater. As used herein, “approximately” may refer to a range that is within ten percent of the stated value. For example, approximately 50 nm may refer to a range between 45 nm and 55 nm. More particularly, any seed layer etching process will result in high average surface roughness. That is, when the surface roughness of a pad 112 is greater than approximately 50 nm, then it can be presumed that a seed layer was present and removed with an etching process. This is certainly the case when residual traces of a seed layer 115 (e.g., titanium) can be found at the interface between the TGV 110 and the glass core 101, or at the interface between the pad 112 and the glass core 101.

Accordingly, embodiments disclosed herein include plating processes that allow for plating of a dielectric layer without the need for a seed layer. Generally, the dielectric layer undergoes a surface activation process, such as a plasma exposure or exposure to an acid (e.g., hydrofluoric acid (HF)). The activation process results in the protonation of the surface in order to form dangling —OH bonds. The —OH bonds can then be ionized to form —O⁻ bonds that are highly reactive with metallic ions in the electroplating bath (e.g., Cu²⁺) in order to promote interfacial bonding and to facilitate conformal metal growth.

In a more particular embodiment, the electroplating processes described herein can be used in order to form high quality TGVs through a glass core that is used for an advanced package substrate architectures. In an embodiment, the TGVs may be high aspect ratio features (e.g., with a height:width aspect ratio of 5:1 or greater). As such, thick glass cores can be used in some embodiments.

In an embodiment, the resulting structure of the TGVs and overlying pads may be used to demonstrate that the described plating process was used. Particularly, there will not be any seed layer provided between the TGV and the glass core or between the pads and the glass core. That is, the interface between metal and glass may be free from titanium in some embodiments. Additionally, the surfaces of the pads will not exhibit the surface roughness that is typical of solutions that use a seed etching process. For example, the surfaces of the pads may have an average surface roughness (Ra) that is approximately 50 nm or less.

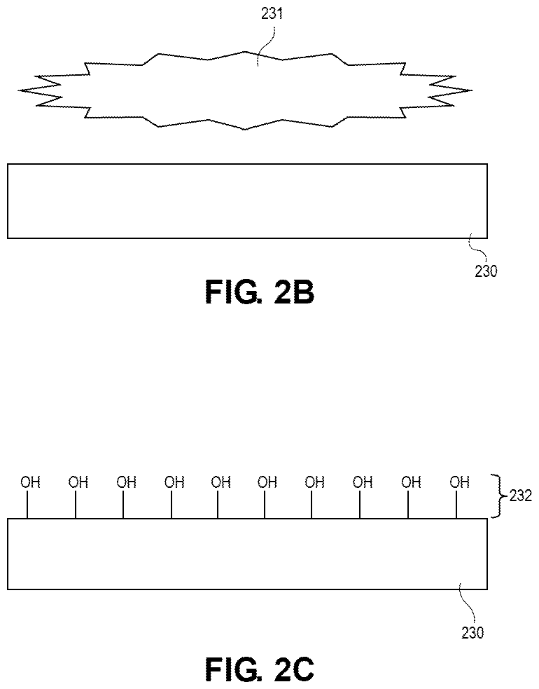

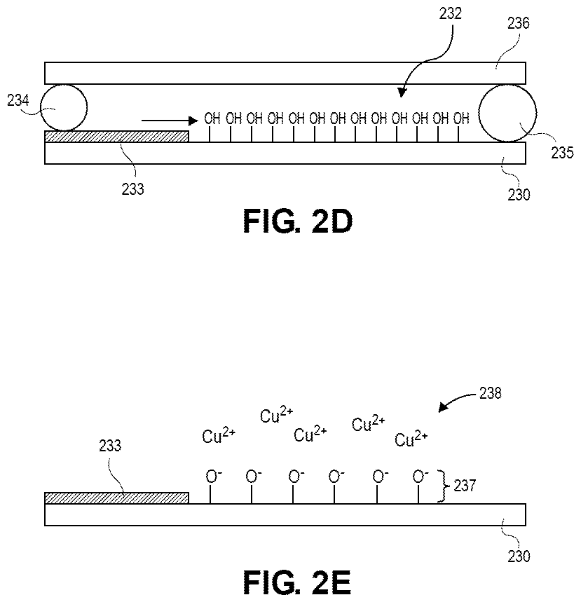

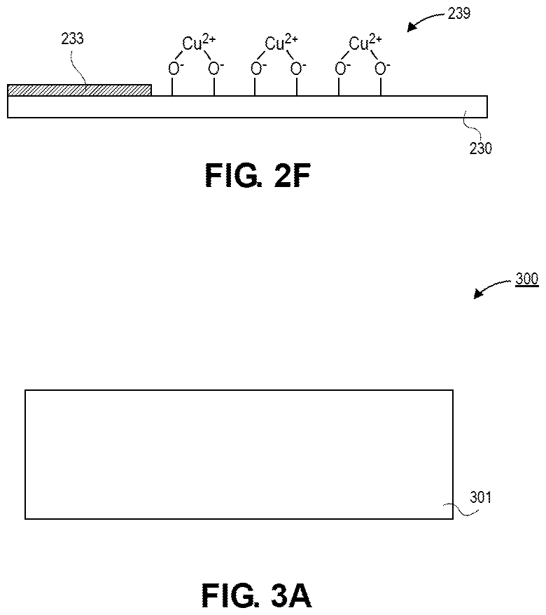

Referring now to FIGS. 2A-2F, a series of cross-sectional illustrations depicting a process for depositing a metal layer over a dielectric layer without a seed lay is shown, in accordance with an embodiment.

Referring now to FIG. 2A, a cross-sectional illustration of a dielectric layer 230 is shown, in accordance with an embodiment. In an embodiment, the dielectric layer 230 may be any suitable dielectric material used in electronic packaging applications. In an embodiment, the dielectric layer 230 may comprise glass. For example, the dielectric layer 230 may be a glass core for a package substrate. The glass may be a borosilicate glass, a fused silica glass, or the like. However, it is to be appreciated that other dielectric layers may also be used, such as buildup film, silicon nitride, or the like. In the illustrated embodiment, the metal layer is plated over the top surface of the dielectric layer 230. As such, a thickness of the dielectric layer 230 can be any thickness.

Referring now to FIG. 2B, a cross-sectional illustration depicting a surface activation process of the dielectric layer 230 is shown, in accordance with an embodiment. In an embodiment, the surface activation process may include exposure of the dielectric layer 230 to a plasma 231. For example, the plasma 231 may be a hydrogen containing plasma. In other embodiments, the plasma 231 may contain oxygen and an inert gas (e.g., argon).

While shown as a plasma activation process, it is to be appreciated that other surface treatments may also be used in some embodiments. In another surface activation treatment, an acid is applied over the surface of the dielectric layer 230. In a particular embodiment, a hydrofluoric acid (HF) is used to treat the surface of the dielectric layer 230. Though, other acids or treatments may be used depending on the material chosen for the dielectric layer 230.

Referring now to FIG. 2C, a cross-sectional illustration of the dielectric layer 230 after the surface activation treatment is shown, in accordance with an embodiment. In an embodiment, the dielectric layer may be protonated. For example, in the case of a glass dielectric layer 230 comprising silicon and oxygen (e.g., SiO₂), the surface activation treatment may result in the formation of —OH dangling bonds 232 at the surface of the dielectric layer 230. In the illustrated embodiment, the entire surface of the dielectric layer 230 was exposed to the surface activation treatment, and the —OH dangling bonds 232 are substantially uniformly formed across an entire surface of the dielectric layer 230. However, it is to be appreciated that a mask or the like may be applied over the dielectric layer 230 in order to locally treat the surface of the dielectric layer 230. A masking step is described in greater detail below.

Referring now to FIG. 2D, a cross-sectional schematic of the plating system is shown, in accordance with an embodiment. The plating system may include a plate 236 of the metal that is desired to be plated on the dielectric layer 230. A first contact 234 is provided on a cathode side and a second contact 235 is provided on an anode side. The first contact 234 and the second contact 235 may be wires or the like. In an embodiment, a conductive layer 233 may be plated, and the front of the conductive layer 233 continues across the surface of the dielectric substrate 230 from the cathode side to the anode side, as indicated by the arrow. The plating system may be provided in an electroplating bath (not shown). In an embodiment, the current density applied to the dielectric substrate 230 may be approximately 10 mA/cm² or more. At such high current densities (e.g., higher than a critical density of copper), the deposit of the conductive layer 233 is uniform and exhibits a stable flat front on scales between approximately 100 μm and approximately 10 cm.

Referring now to FIG. 2E, a cross-sectional illustration of the dielectric substrate 230 after the —OH dangling bonds 232 are ionized to form —O⁻ bonds 237 is shown, in accordance with an embodiment. Additionally, metal ions (e.g., Cu²⁺) are provided in the electroplating bath. Referring now to FIG. 2F, a cross-sectional illustration of the dielectric substrate 230 after the metal ions join the —O⁻ bonds 237 is shown, in accordance with an embodiment. In an embodiment, the bonds 239 may be ionic bonds 239. The presence of an ionic bonds 239 improves the adhesion between the metal layer and the dielectric substrate 230, which improves reliability of the package substrate. In an embodiment, additional metal (e.g. copper) may then be deposited over the ionic bonds 239 in order to plate up a metal layer over the dielectric substrate 230.

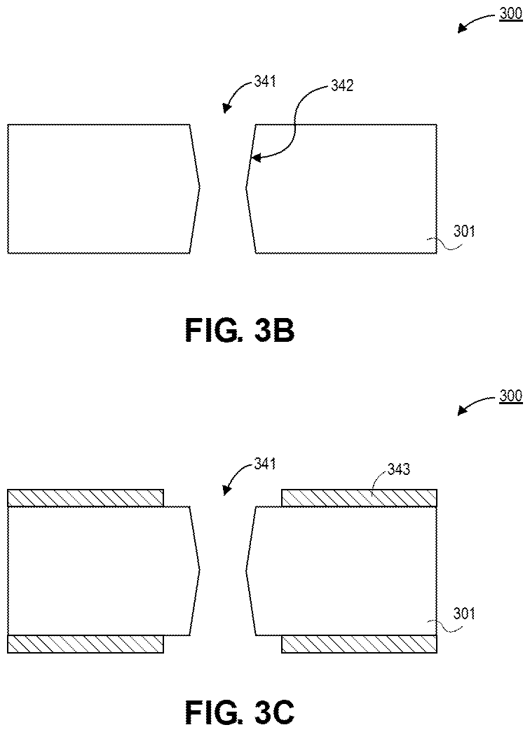

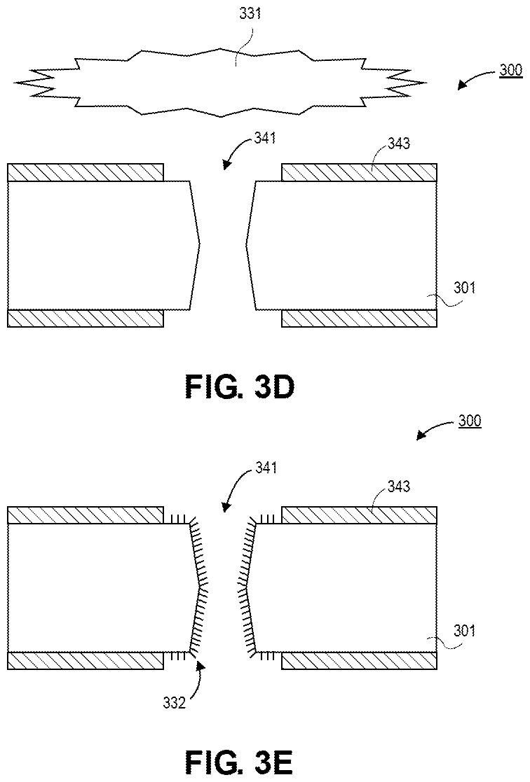

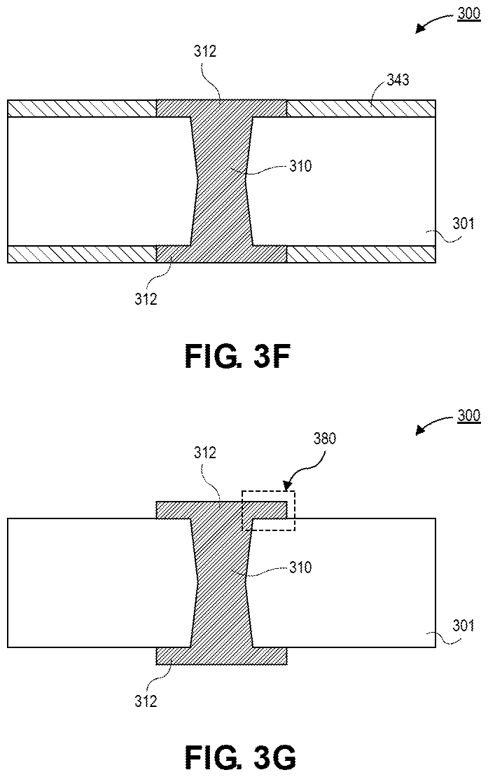

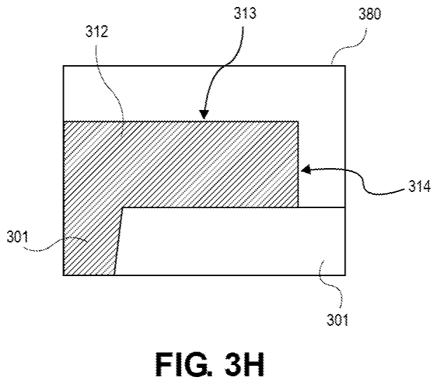

Referring now to FIGS. 3A-3H, a series of cross-sectional illustrations depicting a process for plating a metal layer on a dielectric substrate in a package substrate 300 is shown, in accordance with an embodiment. In an embodiment, the package substrate 300 may include a core 301 with TGVs 310. As will be shown, the metal of the TGVs 310 directly contacts the core 301 without an intervening seed layer.

Referring now to FIG. 3A, a cross-sectional illustration of a package substrate 300 at a stage of manufacture is shown, in accordance with an embodiment. In an embodiment, the package substrate 300 may comprise a core 301. In an embodiment, the core 301 may comprise a dielectric layer. In a more particular embodiment, the core 301 may comprise glass. The core 301 may include a glass that is compatible with laser assisted patterning operation. Laser assisted patterning may include exposing the core 301 to a laser. The laser exposure may result in a phase change in the core 301 that makes the exposed regions more susceptible to an etching chemistry (e.g., a wet etching chemistry). An etching process may then be used to form openings into the core 301. In an embodiment, the core 301 may be any suitable thickness. In an embodiment, the core 301 may have a thickness up to approximately 1,000 μm. Though, thicker cores 301 may also be used in some embodiments.

Referring now to FIG. 3B, a cross-sectional illustration of the core 301 of the package substrate 300 after a via opening 341 is formed is shown, in accordance with an embodiment. In some embodiments, the via opening 341 may be formed with a laser assisted patterning process, such as the process described in greater detail above. The via opening 341 may include tapered sidewalls 342. For example, the sidewalls 342 may have a dual direction taper in order to form an hourglass shaped via opening 341. As used herein, an hourglass shape may refer to a shape that has ends that are wider than a middle of the shape. Such an hourglass shaped via opening 341 may be formed using a dual sided laser exposure process. That is, lasers expose both the top surface and the bottom surface of the core 301. However, in other embodiments (e.g., with thinner cores 301), a single sided laser exposure may be used. In such embodiments, the tapered sidewalls 342 may have a single taper direction through the thickness of the core 301. For example, a top of the via opening 341 may be wider than a bottom of the via opening 341. While described as a laser assisted patterning process, it is to be appreciated that the via opening 341 may be formed with any suitable patterning process. In an embodiment, the via opening 341 may be a high aspect ratio opening. That is, the via opening 341 may have an aspect ratio (height:width) that is approximately 5:1 or greater. In a particular embodiment, the aspect ratio may be approximately 15:1 or greater.

Referring now to FIG. 3C, a cross-sectional illustration of the package substrate 300 after a resist layer 343 is deposited on the core 301 is shown, in accordance with an embodiment. In an embodiment, the resist layer 343 may be a dry film resist (DFR) or the like. In an embodiment, the resist layer 343 may be deposited with a lamination process or the like. The resist layer 343 may be provided on both a top surface and a bottom surface of the core 301. In an embodiment, an opening may be provided through the resist layer 343. The opening in the resist layer 343 may be aligned with the via opening 341. The opening in the resist layer 343 may be wider than the via opening 341. The resist layer 343 may be provided in locations of the core 301 where no conductive material is desired. That is, the conductive material will only be deposited within the opening in the resist layer 343.

Referring now to FIG. 3D, a cross-sectional illustration of the package substrate 300 during a surface treatment process is shown, in accordance with an embodiment. In an embodiment, the surface treatment process may include a plasma treatment. The plasma treatment may include a plasma 331 that is a hydrogen plasma, an oxygen plasma, and/or an inert plasma (e.g., argon). The plasma 331 may interact with the exposed surfaces of the core 301. That is, portions of the top and bottom of the core 301 adjacent to the via opening 341 and the sidewalls of the via opening 341 may be modified by the plasma 331. While a plasma surface treatment is described in FIG. 3D, it is to be appreciated that other treatment types may also be used in some embodiments. For example, an acid treatment may be used in some embodiments. Suitable acids may include hydrofluoric acid (HF) and the like.

Referring now to FIG. 3E, a cross-sectional illustration of the package substrate 300 after the surface treatment is shown, in accordance with an embodiment. In an embodiment, the surface treatment may include a protonation treatment that result in dangling bonds 332 of —OH. The dangling bonds 332 may be provided on the exposed surface of the core 301. That is portions of the core 301 under the resist layer 343 may not be protonated to form —OH dangling bonds 332. The dangling bonds 332 may be provided on the top surface and the bottom surface of the core 301 as well as on the sidewalls of the via opening 341.

Referring now to FIG. 3F, a cross-sectional illustration of the package substrate 300 after the metal is plated is shown, in accordance with an embodiment. In an embodiment, the package substrate 300 may be inserted into a plating bath, such as the plating bath described in greater detail above. The plating bath may ionize the —OH dangling bonds 332 to form —O⁻ bonds. The —O⁻ bonds may ionically bond to metal ions (e.g., Cu²⁺) in the plating bath in order to form the TGV 310 and the pads 312. The TGV 310 may have an aspect ratio that matches the aspect ratio of the via openings 341. Additionally, the TGV 310 may have tapered sidewalls that conform to the shape of the via openings 341. In an embodiment, the TGV 310 and the pads 312 may directly contact the core 301 without an intervening seed layer. That is, in some embodiments, the interface between the via 341 and the core 301 may be free from seed layer constituents, such as titanium. In a particular embodiment, the via 341 may have a uniform composition throughout. That is, a composition of the via 341 at a middle of the via 341 is substantially the same as a composition of the via 341 at the interface between the via 341 and the core 301. For example, the middle of the via 341 may comprise substantially all copper, and the edge of the via 341 at the interface with the core 301 may also comprise substantially all copper.

Referring now to FIG. 3G, a cross-sectional illustration of the package substrate 300 after the resist layers 343 are removed is shown, in accordance with an embodiment. The resist layers 343 may be removed with a resist stripping process, an etching process, or the like. In an embodiment, the resist layers 343 are shown as being removed after the metal plating. In other embodiments, the resist layers 343 may be removed prior to the plating. As shown in the region 380, the TGV 310 and the pad 312 may directly contact the surface of the core 301.

Referring now to FIG. 3H, a zoomed in cross-section of the region 380 is shown, in accordance with an embodiment. As shown, the TGV 310 and the pad 312 directly contact the core 301 without the presence of an intervening seed layer. Additionally, it is to be appreciated that the surfaces of the pad 312 are substantially smooth. For example, an average roughness (Ra) of the top surface 313 and the sidewall surface 314 of the pad 312 may be approximately 50 nm or less. The smooth top surface 313 and sidewall surface 314 are provided because there is no need for a seed layer removal step, such as a flash etching process. That is, there is no residual seed layer over the top and bottom surface of the core 301 that needs to be removed after formation of the pads 312 and the TGV 310.

In an embodiment, after formation of the TGV 310 and the pads 312, the processing of the package substrate 300 may continue with any suitable package assembly processes. For example, buildup layers (e.g., comprising a dielectric) may be laminated above and/or below the core 301. Conductive features (e.g., pads, vias, traces, etc.) may be embedded in the buildup layers in order to provided electrical coupling between the top and bottom of the package substrate 300 and the TGV 310.

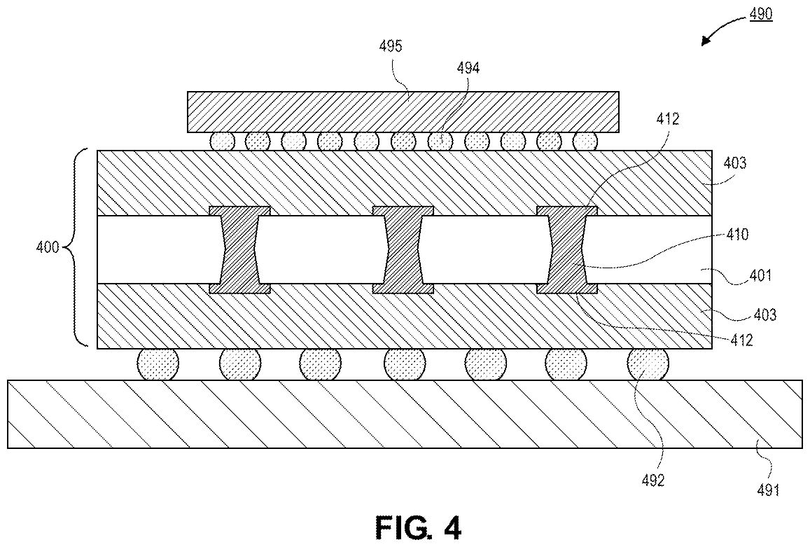

Referring now to FIG. 4, a cross-sectional illustration of an electronic system 490 is shown, in accordance with an embodiment. In an embodiment, the electronic system 490 may comprise a board 491, such as a printed circuit board (PCB) or the like. In an embodiment, the board 491 may be coupled to a package substrate 400 by interconnects 492. In the embodiment shown, the interconnects 492 are solder balls. Though, it is to be appreciated that the interconnects 492 may comprise any suitable interconnect architecture, such as sockets or the like.

In an embodiment, the package substrate 400 may comprise a core 401. The core 401 may be a dielectric material. In a particular embodiment, the core 401 may comprise glass. The core 401 may comprise a glass that is suitable for laser assisted patterning operations. In an embodiment TGVs 410 may be provided through a thickness of the core 401. In an embodiment, the TGVs 410 may be formed without a seed layer. That is, the TGVs 410 may directly contact and interface with the core 401. For example, the bond between the TGVs 410 and the core 401 may be an ionic bond in some embodiments. The TGVs 410 may be high aspect ratio features. For example, the TGVs 410 may have an aspect ratio of 5:1 or greater or 15:1 or greater. Pads 412 may be provided above and below the TGVs 410. In an embodiment, the pads 412 may also be formed without a seed layer. The pads 412 may directly contact the core 401. Additionally, the pads 412 may have smooth surfaces. For example, the pads 412 may have an average roughness that is approximately 50 nm or less in some embodiments.

In an embodiment, the package substrate 400 may further comprise buildup layers 403 over and under the core 401. The buildup layers 403 may include electrical routing (e.g., pads, traces, vias, etc.) that electrically couple with the TGVs 410. The electrical routing in the buildup layers 403 is omitted from FIG. 4 for simplicity.

In an embodiment, the package substrate 400 may be coupled to one or more dies 495. For example, interconnects 494 may couple the package substrate 400 to the die 495. While shown as solder balls, it is to be appreciated that any first level interconnect (FLI) architecture may be used for the interconnects 494. In an embodiment, a single die 495 is show. Though, it is to be appreciated that additional dies 495 may also be coupled to the package substrate 400. In some embodiments, a pair of dies 495 may be coupled together through a bridge die (not shown) in the buildup layers 403. In an embodiment, the die 495 may include a compute die (e.g., a processor, a graphics processor, an ASIC, a system on a chip (SoC), or the like). In other embodiments, the die 495 may be a memory die or any other type of die.

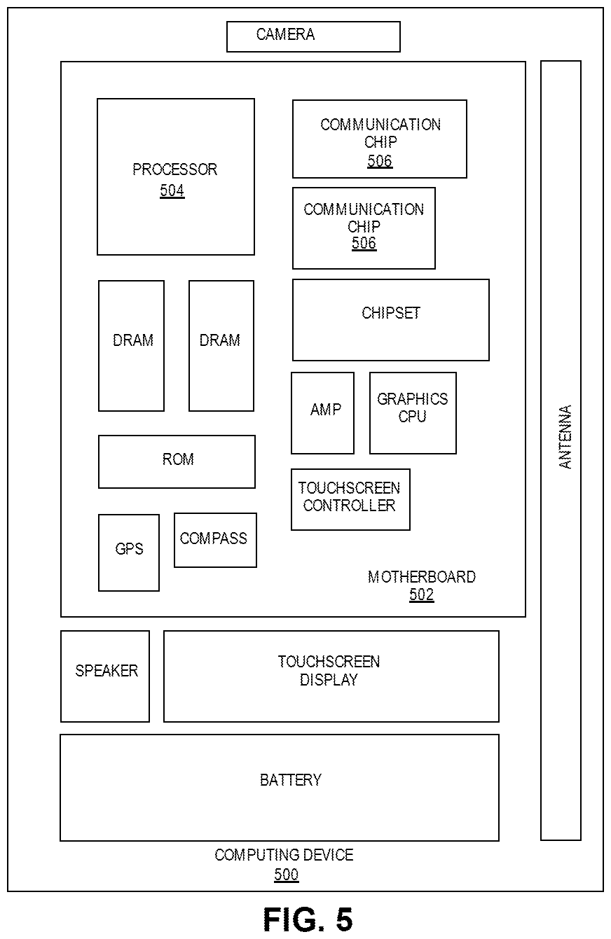

FIG. 5 illustrates a computing device 500 in accordance with one implementation of the invention. The computing device 500 houses a board 502. The board 502 may include a number of components, including but not limited to a processor 504 and at least one communication chip 506. The processor 504 is physically and electrically coupled to the board 502. In some implementations the at least one communication chip 506 is also physically and electrically coupled to the board 502. In further implementations, the communication chip 506 is part of the processor 504.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 506 enables wireless communications for the transfer of data to and from the computing device 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 506 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 500 may include a plurality of communication chips 506. For instance, a first communication chip 506 may be dedicated to shorter range wireless communications such as Wi-Fi and Bluetooth and a second communication chip 506 may be dedicated to longer range wireless communications such as GPS, EDGE, GPRS, CDMA, WiMAX, LTE, Ev-DO, and others.

The processor 504 of the computing device 500 includes an integrated circuit die packaged within the processor 504. In some implementations of the invention, the integrated circuit die of the processor may be part of an electronic package that comprises a glass core with TGVs that are formed without a seed layer and which directly contact the core, in accordance with embodiments described herein. The term “processor” may refer to any device or portion of a device that processes electronic data from registers and/or memory to transform that electronic data into other electronic data that may be stored in registers and/or memory.

The communication chip 506 also includes an integrated circuit die packaged within the communication chip 506. In accordance with another implementation of the invention, the integrated circuit die of the communication chip may be part of an electronic package that comprises a glass core with TGVs that are formed without a seed layer and which directly contact the core, in accordance with embodiments described herein.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: a package substrate, comprising: a layer, wherein the layer is a dielectric material; a via opening through a thickness of the layer; and a conductive via in the via opening, wherein the conductive via has a substantially uniform composition throughout a thickness of the conductive via, and wherein the conductive via directly contacts the layer.

Example 2: the package substrate of Example 1, wherein the layer comprises glass.

Example 3: the package substrate of Example 1 or Example 2, wherein the conductive via comprises copper.

Example 4: the package substrate of Examples 1-3, wherein a bond between the conductive via and the layer is an ionic bond.

Example 5: the package substrate of Example 4, wherein ions of the conductive via are bonded to oxygen of the layer.

Example 6: the package substrate of Examples 1-5, further comprising: a pad over a top surface of the layer and connected to the conductive via.

Example 7: the package substrate of Example 6, wherein a surface of the pad has an average surface roughness (Ra) that is less than approximately 50 nm.

Example 8: the package substrate of Example 6 or Example 7, wherein the pad directly contacts the layer.

Example 9: the package substrate of Examples 1-8, wherein the layer is a core of a package substrate.

Example 10: the package substrate of Examples 1-9, wherein the conductive via has an aspect ratio (height:width) that is approximately 5:1 or greater.

Example 11: the package substrate of Examples 1-10, wherein there is no seed layer between the conductive via and the layer.

Example 12: the package substrate of Examples 1-11, wherein the package substrate is a core for an electronic package, and wherein the electronic package is coupled to a board.

Example 13: an electroplating cell, comprising: a metal plate with an anode side and a cathode side; a dielectric substrate below the metal plate; a first contact between the metal plate and the dielectric substrate at the anode side; and a second contact between the metal plate and the dielectric substrate at the cathode side.

Example 14: the electroplating cell of Example 13, wherein the electroplating cell is provided in a plating bath.

Example 15: the electroplating cell of Example 13 or Example 14, wherein plating on the dielectric substrate starts at the cathode side and progresses to the anode side.

Example 16: the electroplating cell of Examples 13-15, wherein the dielectric substrate is activated with —OH dangling bonds.

Example 17: the electroplating cell of Example 16, wherein the —OH dangling bonds are ionized to form —O⁻ bonds.

Example 18: the electroplating cell of Examples 13-17, wherein the current density applied to the dielectric substrate is approximately 10 mA/cm² or greater.

Example 19: the electroplating cell of Examples 13-18, wherein the plating on the dielectric substrate is substantially uniform and exhibits a stable flat front with a width between 100 μm and 10 cm.

Example 20: the electroplating cell of Examples 13-19, wherein the dielectric substrate is removed from the electroplating cell and assembled as a core of an electronic package.

Example 21: an electronic system, comprising: a board; a package substrate coupled to the board, wherein the package substrate comprises: a core, wherein the core comprises glass; a through glass via (TGV) through the core, wherein the TGV directly contacts the core without an intervening seed layer; and buildup layers over the core; and a die coupled to the package substrate.

Example 22: the electronic system of Example 21, wherein the TGV is ionically bonded to the core.

Example 23: the electronic system of Example 22, wherein ions of the TGV are bonded to oxygen of the core.

Example 24: the electronic system of Example 21-23, further comprising: a pad over the TGV, wherein the pad has an average surface roughness (Ra) of less than approximately 50 nm.

Example 25: the electronic system of Examples 21-24, wherein the TGV has an aspect ratio (height:width) that is approximately 5:1 or greater.

What is claimed is:

1. A package substrate, comprising:
a layer, wherein the layer is a dielectric material;
a via opening through a thickness of the layer; and
a conductive via in the via opening, wherein the conductive via has a substantially uniform composition throughout a thickness of the conductive via, and wherein the conductive via directly contacts the layer.

2. The package substrate of claim 1, wherein the layer comprises glass.

3. The package substrate of claim 1, wherein the conductive via comprises copper.

4. The package substrate of claim 1, wherein a bond between the conductive via and the layer is an ionic bond.

5. The package substrate of claim 4, wherein ions of the conductive via are bonded to oxygen of the layer.

6. The package substrate of claim 1, further comprising:
a pad over a top surface of the layer and connected to the conductive via.

7. The package substrate of claim 6, wherein a surface of the pad has an average surface roughness (Ra) that is less than approximately 50 nm.

8. The package substrate of claim 6, wherein the pad directly contacts the layer.

9. The package substrate of claim 1, wherein the layer is a core of a package substrate.

10. The package substrate of claim 1, wherein the conductive via has an aspect ratio (height:width) that is approximately 5:1 or greater.

11. The package substrate of claim 1, wherein there is no seed layer between the conductive via and the layer.

12. The package substrate of claim 1, wherein the package substrate is a core for an electronic package, and wherein the electronic package is coupled to a board.

13. An electroplating cell, comprising:
a metal plate with an anode side and a cathode side;
a dielectric substrate below the metal plate;
a first contact between the metal plate and the dielectric substrate at the anode side; and
a second contact between the metal plate and the dielectric substrate at the cathode side.

14. The electroplating cell of claim 13, wherein the electroplating cell is provided in a plating bath.

15. The electroplating cell of claim 13, wherein plating on the dielectric substrate starts at the cathode side and progresses to the anode side.

16. The electroplating cell of claim 13, wherein the dielectric substrate is activated with —OH dangling bonds.

17. The electroplating cell of claim 16, wherein the —OH dangling bonds are ionized to form —O⁻ bonds.

18. The electroplating cell of claim 13, wherein the current density applied to the dielectric substrate is approximately 10 mA/cm² or greater.

19. The electroplating cell of claim 13, wherein the plating on the dielectric substrate is substantially uniform and exhibits a stable flat front with a width between 100 μm and 10 cm.

20. The electroplating cell of claim 13, wherein the dielectric substrate is removed from the electroplating cell and assembled as a core of an electronic package.

21. An electronic system, comprising:
a board;
a package substrate coupled to the board, wherein the package substrate comprises:
a core, wherein the core comprises glass;
a through glass via (TGV) through the core, wherein the TGV directly contacts the core without an intervening seed layer; and
buildup layers over the core; and
a die coupled to the package substrate.

22. The electronic system of claim 21, wherein the TGV is ionically bonded to the core.

23. The electronic system of claim 22, wherein ions of the TGV are bonded to oxygen of the core.

24. The electronic system of claim 21, further comprising:
a pad over the TGV, wherein the pad has an average surface roughness (Ra) of less than approximately 50 nm.

25. The electronic system of claim 21, wherein the TGV has an aspect ratio (height:width) that is approximately 5:1 or greater.
